(19) United States
(12) Patent Application Publication
(10) Pub. No.: US 2019/0074505 A1
(43) Pub. Date: Mar. 7, 2019

(54) METHOD FOR MANUFACTURING ELECTROCHEMICAL DEVICE

(71) Applicant: Institute of Nuclear Energy Research, Automic Energy Council, Executive Yuan, R.O.C., Taoyuan (TW)

(72) Inventors: MIN-CHUAN WANG, Taoyuan (TW); YU-CHEN LI, Taoyuan (TW); SHENG-CHUAN HSU, Taoyuan (TW); JIN-YU WU, Taoyuan (TW); DER-JUN JAN, Taoyuan (TW)

(21) Appl. No.: 15/812,162

(22) Filed: Nov. 14, 2017

(30) Foreign Application Priority Data
Sep. 1, 2017 (TW) 106130039

(51) Int. Cl. H01M 4/04; G02F 1/155; H01M 10/0585; C23C 16/50; C23C 16/06

(52) U.S. Cl. CPC H01M 4/0471; G02F 1/155; H01M 10/0585; G02F 2001/1555; H01M 4/0407; C23C 16/50; C23C 16/06; H01M 4/0404

(57) ABSTRACT

A method for manufacturing electrochemical device, which may include the following steps: disposing a metal material or a metal oxide material to be doped on the anode of the plasma source of the arc plasma coating equipment; forming a metal oxide film of the electrochemical device by the arc plasma coating equipment via an arc plasma coating process; and doping the metal material or the metal oxide material into the metal oxide film after being mixed with the plasma by heat vaporization via the phenomenon of the electrons heating the anode of the plasma source.

### CROSS-REFERENCE TO RELATED APPLICATION

This application claims the benefit of Taiwan Patent Application No.106130039, filed on Sep. 1, 2017, in the Taiwan Intellectual Property Office, the disclosure of which is incorporated herein in its entirety by reference.

### BACKGROUND OF THE INVENTION

### 1. Field of the Invention

The present invention generally relates to a method for manufacturing electrochemical device, in particular to a method for manufacturing electrochemical device by doping a metal material or a metal oxide material in a metal oxide film via the arc plasma coating technology.

### 2. Description of the Related Art

In recent years, with the greenhouse effect becoming more serious, it has become a major target to save energy for all countries over the world. Glass windows have been comprehensively applied to modern buildings and vehicles; however, glass windows will result in high temperature; thus, how to solve the above problem is the key to save more energy.

Smart windows adopt electrochromic devices, which is a kind of electrochemical device with low power consumption; thus, smart windows are very suitable for green buildings; smart windows can actively adjust the transmittances of visible light and radiant heat according to the brightness and the temperature needed by the user in the building; thus, smart windows have great potentialities in the development of the green buildings in the future. Besides, electrochromic device will also be applied to more products in the future.

Secondary batteries are also a kind of electrochemical device, which have been applied to smart phones, cameras, cars and various industrial equipment; in addition, IoT devices, wearable devices and environmental sensors need new appearances and designs, which cannot be achieved by conventional battery technologies. In the future, the applications of secondary batteries will also keep increasing.

However, the above electrochemical devices should be manufactured by the complicated vacuum thin-film technology, which significantly increases the cost of the above electrochemical devices; thus, these electrochemical devices have yet to prevail over the world until now.

The major constituents of currently available electrochemical devices are metal oxides; therefore, these currently available electrochemical devices cannot be put into mass production because the magnetron plasma coating technology is of low efficiency.

Moreover, it is necessary to dope metal ions into metal oxides during the manufacturing processes of these electrochemical devices; however, doping the metal ions into the metal oxides by externally injection will not only significantly increase the cost of the manufacturing process, but also reduce the stability of the manufacturing process. On the other hand, directly introducing metals with low melting point for doping will usually reduce the stability of the targets and increase the difficulty of the manufacturing process; in addition, the coating speed is also low, which will also significantly increase the difficulty of the whole manufacturing process.

Therefore, it has become an important issue to provide a method for manufacturing electrochemical device in order to overcome the drawbacks of the convention methods.

### SUMMARY OF THE INVENTION

Therefore, it is a primary objective of the present invention to provide a method for manufacturing electrochemical device in order to improve the shortcomings of the conventional methods for manufacturing electrochemical device.

To achieve the foregoing objective, the present invention provides a method for manufacturing electrochemical device, which may include the following steps: providing a conductive substrate; disposing a metal material or a metal oxide material to be doped on the anode of the plasma source of an arc plasma coating equipment; and coating an anode film on the conductive substrate by the arc plasma coating equipment via an arc plasma coating process, and doping the metal material or the metal oxide material into the anode film via the phenomenon of the electrons heating the anode of the plasma source.

In a preferred embodiment of the present invention, the method for manufacturing electrochemical device may further include the following step: coating an ion conductor layer on the anode film by the arc plasma coating equipment via the arc plasma coating process, and doping the metal material or the metal oxide material into the ion conductor layer via the phenomenon of the electrons heating the anode of the plasma source.

In a preferred embodiment of the present invention, the method for manufacturing electrochemical device may further include the following step: coating a cathode film on the ion conductor layer by the arc plasma coating equipment via the arc plasma coating process, and doping the metal material or the metal oxide material into the cathode film via the phenomenon of the electrons heating the anode of the plasma source

In a preferred embodiment of the present invention, the method for manufacturing electrochemical device may further include the following step: coating a conductive film on the cathode film by the arc plasma coating equipment via the arc plasma coating process, and doping the metal material or the metal oxide material into the conductive film via the phenomenon of the electrons heating the anode of the plasma source.

In a preferred embodiment of the present invention, the anode film, the ion conductor layer, the cathode film and the conductive film may be doped-type metal oxide films.

In a preferred embodiment of the present invention, the metal material or the metal oxide material may be doped into the anode film, the ion conductor layer, the cathode film and the conductive film after the metal material or the metal oxide material is mixed with plasma via heat vaporization.

In a preferred embodiment of the present invention, the electrochemical device may be a secondary battery or an electrochromic device.

To achieve the foregoing objective, the present invention further provides a method for manufacturing electrochemical device, which may include the following steps: providing a conductive substrate; disposing a metal material or a metal oxide material to be doped on the anode of the plasma source of an arc plasma coating equipment; and coating a cathode film on the conductive substrate by the arc plasma coating equipment via an arc plasma coating process, and doping the metal material or the metal oxide material into the cathode film via the phenomenon of the electrons heating the anode of the plasma source.

In a preferred embodiment of the present invention, the method for manufacturing electrochemical device may further include the following step: coating an ion conductor layer on the cathode film by the arc plasma coating equipment via the arc plasma coating process, and doping the metal material or the metal oxide material into the ion conductor layer via the phenomenon of the electrons heating the anode of the plasma source.

In a preferred embodiment of the present invention, the method for manufacturing electrochemical device may further include the following step: coating an anode film on the ion conductor layer by the arc plasma coating equipment via the arc plasma coating process, and doping the metal material or the metal oxide material into the anode film via the phenomenon of the electrons heating the anode of the plasma source.

In a preferred embodiment of the present invention, the method for manufacturing electrochemical device may further include the following step: coating a conductive film on the anode film by the arc plasma coating equipment via the arc plasma coating process, and doping the metal material or the metal oxide material into the conductive film via the phenomenon of the electrons heating the anode of the plasma source.

In a preferred embodiment of the present invention, the anode film, the ion conductor layer, the cathode film and the conductive film may be doped-type metal oxide films.

In a preferred embodiment of the present invention, the metal material or the metal oxide material may be doped into the anode film, the ion conductor layer, the cathode film and the conductive film after the metal material or the metal oxide material is mixed with plasma via heat vaporization.

In a preferred embodiment of the present invention, the electrochemical device may be a secondary battery or an electrochromic device.

To achieve the foregoing objective, the present invention still further provides a method for manufacturing electrochemical device, which may include the following steps: disposing a metal material or a metal oxide material to be doped on the anode of the plasma source of an arc plasma coating equipment; forming a metal oxide film of the electrochemical device by the arc plasma coating equipment via an arc plasma coating process; and doping the metal material or the metal oxide material into the metal oxide film via the phenomenon of electrons heating the anode of the plasma source.

In a preferred embodiment of the present invention, the metal oxide film may be formed on a conductive substrate.

In a preferred embodiment of the present invention the metal oxide film may be a doped-type metal oxide film.

In a preferred embodiment of the present invention, the metal oxide film may be an anode film, an ion conductor layer, a cathode film or a conductive film.

In a preferred embodiment of the present invention, the metal material or the metal oxide material may be doped into the metal oxide film after the metal material or the metal oxide material is mixed with plasma via heat vaporization.

In a preferred embodiment of the present invention, the electrochemical device may be a secondary battery or an electrochromic device.

The method for manufacturing electrochemical device in accordance with the embodiments of the present invention may have the following advantages:

(1) In one embodiment of the present invention, the method for manufacturing electrochemical device can form the doped-type metal oxide films via the arc plasma coating process, which can effectively increase the coating rate and the deposition speed; thus, the cost of the electrochemical devices can be reduced, such that the electrochemical devices can be put into mass production.

(2) In one embodiment of the present invention, the method for manufacturing electrochemical device can directly dope the metal materials or the metal oxide materials into the metal oxide films via the phenomenon of the electrons heating the anode of the plasma source during the arc plasma coating process, which can reduce the simplify the manufacturing process and further reduce the cost.

(3) In one embodiment of the present invention, the method for manufacturing electrochemical device can form the doped-type metal oxide films via the arc plasma coating process, which can effectively increase the ion conduction speed and the response time of the doped-type metal oxide films, so can improve the characteristics of the electrochemical devices.

(4) In one embodiment of the present invention, the method for manufacturing electrochemical device can form the doped-type metal oxide films via the arc plasma coating process, so the doped-type metal oxide films can have the Nano-porous structure, which can further improve the characteristics of the electrochemical devices.

(5) In one embodiment of the present invention, the method for manufacturing electrochemical device can be applied to various electrochemical devices, so is more comprehensive in use.

### BRIEF DESCRIPTION OF THE DRAWINGS

The detailed structure, operating principle and effects of the present invention will now be described in more details hereinafter with reference to the accompanying drawings that show various embodiments of the invention as follows.

FIG. 1 is a schematic view of an electrochemical device of a first embodiment in accordance with the present invention.

FIG. 2 is a flow chart of a method for manufacturing the electrochemical device of the first embodiment in accordance with the present invention.

FIG. 3 is a schematic view of an electrochemical device of a second embodiment in accordance with the present invention.

FIG. 4 is a flow chart of a method for manufacturing the electrochemical device of the second embodiment in accordance with the present invention.

### DETAILED DESCRIPTION OF THE PREFERRED EMBODIMENTS

The technical content of the present invention will become apparent by the detailed description of the following embodiments and the illustration of related drawings as follows.

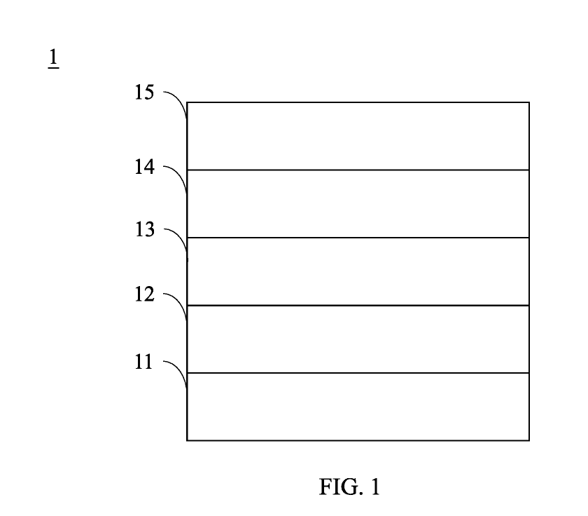

With reference to FIG. 1 for a schematic view of an electrochemical device of a first embodiment in accordance with the present invention, the electrochemical device 1 may include a conductive substrate 11, an anode film 12, an ion conductor layer 13, a cathode film 14 and a conductive film 15.

The anode film 12 may be disposed on the conductive substrate 11.

The ion conductor layer 13 may be disposed on the anode film 12.

The cathode film 14 may be disposed on the ion conductor layer 13.

The conductive film 15 may be disposed on the cathode film 14.

In the embodiment, the anode film 12, the ion conductor layer 13, the cathode film 14 and the conductive film 15 may be doped-type metal oxide films.

The manufacturing method of the electrochemical device 1 of the embodiment can form the anode film 12, the ion conductor layer 13, the cathode film 14 and the conductive film 15 on the conductive substrate 11; more specifically, a metal material or a metal oxide material to be doped may be disposed at the anode of the plasma source of the arc plasma coating equipment; then, the metal material or the metal oxide material can be doped into the anode film 12, the ion conductor layer 13, the cathode film 14 and the conductive film 15 via the phenomenon of the electrons heating the anode of the plasma source; in a preferred embodiment, the above metal material or the metal oxide material may be Li, Mg, Na, etc., or the oxides thereof.

First, the user can coat the anode film 12 on the conductive substrate 11 by the arc plasma coating equipment via the arc plasma coating process; as the metal material or the metal oxide material is disposed at the anode of the plasma source of the arc plasma coating equipment, the metal material or the metal oxide material can be simultaneously doped into the anode film 12 after being mixed with the plasma via heat vaporization by the phenomenon of the electrons heating the anode of the plasma source when the anode film 12 is being coated on the conductive substrate 11.

Similarly, the user can coat the ion conductor layer 13 on the anode film 12 by the arc plasma coating equipment via the arc plasma coating process; the metal material or the metal oxide material can be simultaneously doped into the ion conductor layer 13 after being mixed with the plasma via heat vaporization by the phenomenon of the electrons heating the anode of the plasma source when the ion conductor layer 13 is being coated on the anode film 12.

Next, the user can coat the cathode film 14 on the ion conductor layer 13 by the arc plasma coating equipment via the arc plasma coating process; the metal material or the metal oxide material can be simultaneously doped into the cathode film 14 after being mixed with the plasma via heat vaporization by the phenomenon of the electrons heating the anode of the plasma source when the cathode film 14 is being coated on the ion conductor layer 13.

Finally, the user can coat the conductive film 15 on the cathode film 14 by the arc plasma coating equipment via the arc plasma coating process; the metal material or the metal oxide material can be simultaneously doped into the conductive film 15 after being mixed with the plasma via heat vaporization by the phenomenon of the electrons heating the anode of the plasma source when the conductive film 15 is being coated on the cathode film 14; then, the manufacturing process of the electrochemical device 1 is finished. As described above, the method for manufacturing the electrochemical device 1 of the embodiment can be applied to manufacture any one of the layers of the electrochemical device, which is included within the scope of the following claims.

According to the description above, the method for manufacturing electrochemical device 1 of the embodiment can form the doped-type metal oxide films via the arc plasma coating process, which can effectively increase the coating rate and the deposition speed; thus, the cost of the electrochemical device 1 can be reduced, such that the electrochemical device 1 can be put into mass production. Besides, the method for manufacturing electrochemical device 1 of the embodiment can directly dope the metal material or the metal oxide material into the metal oxide films via the phenomenon of the electrons heating the anode of the plasma source during the arc plasma coating process, which can reduce the simplify the manufacturing process and further reduce the cost. Further, the method for manufacturing electrochemical device 1 of the embodiment can form the doped-type metal oxide films via the arc plasma coating process, which can effectively increase the ion conduction speed and the response time of the doped-type metal oxide films, so can improve the characteristics of the electrochemical device 1. Accordingly, the method for manufacturing electrochemical device 1 of the embodiment can exactly improve the drawbacks of prior art.

The embodiment just exemplifies the present disclosure and is not intended to limit the scope of the present disclosure; any equivalent modification and variation according to the spirit of the present disclosure is to be also included within the scope of the following claims and their equivalents.

It is worthy to point out that the electrochemical devices should be manufactured by the complicated vacuum thin-film technology, which significantly increases the cost of the electrochemical devices; thus, these electrochemical devices have yet to prevail over the world until now; in addition, the major constituents of currently available electrochemical devices are metal oxides; therefore, these electrochemical devices cannot be put into mass production because the magnetron plasma coating technology is of low efficiency. On the contrary, according to one embodiment of the present invention, the method for manufacturing electrochemical device can form the doped-type metal oxide films via the arc plasma coating process, which can effectively increase the coating rate and the deposition speed; thus, the cost of the electrochemical devices can be reduced, such that the electrochemical devices can be put into mass production.

Besides, it is necessary to dope metal ions into metal oxides during the manufacturing processes of these electrochemical devices; however, doping the metal ions into the metal oxides by externally injection will not only significantly increase the cost of the manufacturing process, but also reduce the stability of the manufacturing process; on the other hand, directly introducing metals with low melting point for doping will usually reduce the stability of the targets and increase the difficulty of the manufacturing process; in addition, the coating speed is also low, which will also significantly increase the difficulty of the whole manufacturing process. On the contrary, according to one embodiment of the present invention, the method for manufacturing electrochemical device can directly dope the metal materials or the metal oxide materials into the metal oxide films via the phenomenon of the electrons heating the anode of the plasma source during the arc plasma coating process, which can reduce the simplify the manufacturing process and further reduce the cost.

Further, according to one embodiment of the present invention, the method for manufacturing electrochemical device can form the doped-type metal oxide films via the arc plasma coating process, which can effectively increase the ion conduction speed and the response time of the doped-type metal oxide films, so can improve the characteristics of the electrochemical devices.

Moreover, according to one embodiment of the present invention, the method for manufacturing electrochemical device can form the doped-type metal oxide films via the arc plasma coating process, so the doped-type metal oxide films can have the Nano-porous structure, which can further improve the characteristics of the electrochemical devices.

Furthermore, according to one embodiment of the present invention, the method for manufacturing electrochemical device can be applied to various electrochemical devices, so is more comprehensive in use. As described above, the present invention definitely has inventive step.

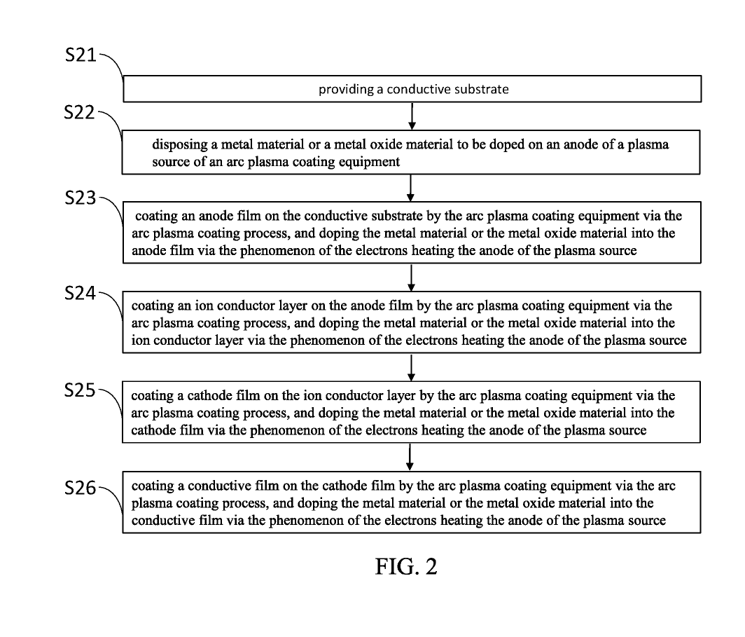

With reference to FIG. 2 for a flow chart of a method for manufacturing the electrochemical device of the first embodiment in accordance with the present invention. As shown in FIG. 2, the method for manufacturing electrochemical device 1 of the embodiment may include the following steps:

Step S21: providing a conductive substrate.

Step S22: disposing a metal material or a metal oxide material to be doped on an anode of a plasma source of an arc plasma coating equipment.

Step S23: coating an anode film on the conductive substrate by the arc plasma coating equipment via the arc plasma coating process, and doping the metal material or the metal oxide material into the anode film via the phenomenon of the electrons heating the anode of the plasma source.

Step S24: coating an ion conductor layer on the anode film by the arc plasma coating equipment via the arc plasma coating process, and doping the metal material or the metal oxide material into the ion conductor layer via the phenomenon of the electrons heating the anode of the plasma source.

Step S25: coating a cathode film on the ion conductor layer by the arc plasma coating equipment via the arc plasma coating process, and doping the metal material or the metal oxide material into the cathode film via the phenomenon of the electrons heating the anode of the plasma source.

Step S26: coating a conductive film on the cathode film by the arc plasma coating equipment via the arc plasma coating process, and doping the metal material or the metal oxide material into the conductive film via the phenomenon of the electrons heating the anode of the plasma source.

The embodiment just exemplifies the present disclosure and is not intended to limit the scope of the present disclosure; any equivalent modification and variation according to the spirit of the present disclosure is to be also included within the scope of the following claims and their equivalents.

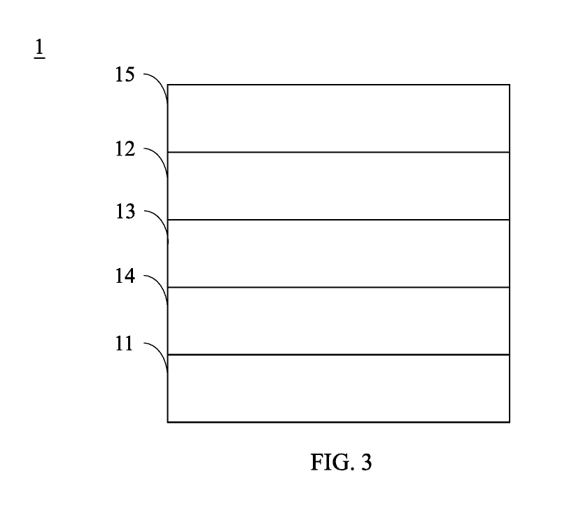

With reference to FIG. 3 for a schematic view of an electrochemical device of a second embodiment in accordance with the present invention, the electrochemical device 1 may include a conductive substrate 11, a cathode film 14, an ion conductor layer 13, an anode film 12 and a conductive film 15.

The cathode film 14 may be disposed on the conductive substrate 11.

The ion conductor layer 13 may be disposed on the cathode film 14.

The anode film 12 may be disposed on the ion conductor layer 13.

The conductive film 15 may be disposed on the anode film 12.

Similarly, in the embodiment, the cathode film 14, the ion conductor layer 13, the anode film 12 and the conductive film 15 may be doped-type metal oxide films.

The manufacturing method of the electrochemical device 1 of the embodiment can form the cathode film 14, the ion conductor layer 13, the anode film 12 and the conductive film 15 on the conductive substrate 11; similarly, a metal material or a metal oxide material to be doped may be disposed at the anode of the plasma source of the arc plasma coating equipment; then, the metal material or the metal oxide material can be doped into the cathode film 14, the ion conductor layer 13, the anode film 12 and the conductive film 15 via the phenomenon of the electrons heating the anode of the plasma source.

Accordingly, the difference between the embodiment and the previous embodiment is that the cathode film 14 is, in the embodiment, coated on the conductive substrate 11 first; then, the ion conductor layer 12 is coated on the cathode film 14; afterward, the anode film 12 is coated on the ion conductor layer 13; finally, the conductive film 15 is coated on the anode film 12.

The embodiment just exemplifies the present disclosure and is not intended to limit the scope of the present disclosure; any equivalent modification and variation according to the spirit of the present disclosure is to be also included within the scope of the following claims and their equivalents.

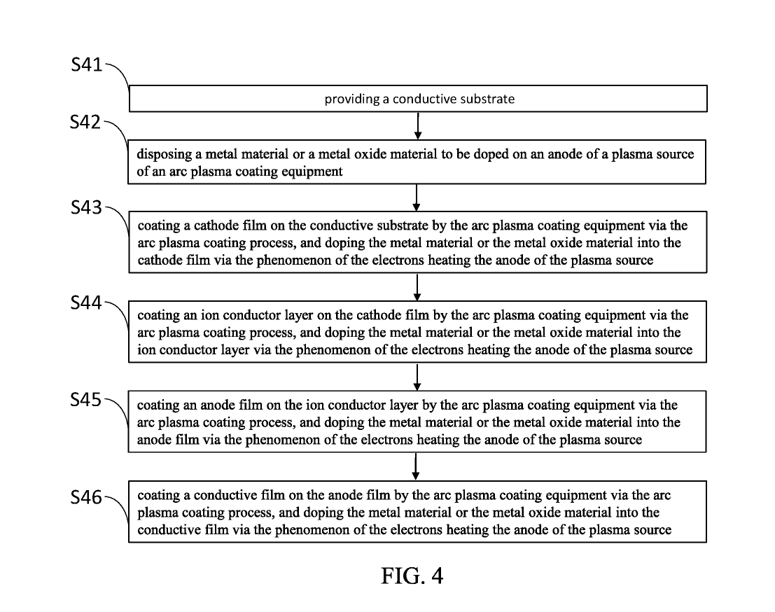

With reference to FIG. 4 for a flow chart of a method for manufacturing the electrochemical device of the second embodiment in accordance with the present invention. As shown in FIG. 4, the method for manufacturing electrochemical device 1 of the embodiment may include the following steps:

Step S41: providing a conductive substrate.

Step S42: disposing a metal material or a metal oxide material to be doped on an anode of a plasma source of an arc plasma coating equipment.

Step S43: coating a cathode film on the conductive substrate by the arc plasma coating equipment via the arc plasma coating process, and doping the metal material or the metal oxide material into the cathode film via the phenomenon of the electrons heating the anode of the plasma source.

Step S44: coating an ion conductor layer on the cathode film by the arc plasma coating equipment via the arc plasma coating process, and doping the metal material or the metal oxide material into the ion conductor layer via the phenomenon of the electrons heating the anode of the plasma source.

Step S45: coating an anode film on the ion conductor layer by the arc plasma coating equipment via the arc plasma coating process, and doping the metal material or the metal oxide material into the anode film via the phenomenon of the electrons heating the anode of the plasma source.

Step S46: coating a conductive film on the anode film by the arc plasma coating equipment via the arc plasma coating process, and doping the metal material or the metal oxide material into the conductive film via the phenomenon of the electrons heating the anode of the plasma source.

The embodiment just exemplifies the present disclosure and is not intended to limit the scope of the present disclosure; any equivalent modification and variation according to the spirit of the present disclosure is to be also included within the scope of the following claims and their equivalents.

To sum up, according to one embodiment of the present invention, the method for manufacturing electrochemical device can form the doped-type metal oxide films via the arc plasma coating process, which can effectively increase the coating rate and the deposition speed; thus, the cost of the electrochemical devices can be reduced, such that the electrochemical devices can be put into mass production.

Also, according to one embodiment of the present invention, the method for manufacturing electrochemical device can directly dope the metal materials or the metal oxide materials into the metal oxide films via the phenomenon of the electrons heating the anode of the plasma source during the arc plasma coating process, which can reduce the simplify the manufacturing process and further reduce the cost.

Besides, according to one embodiment of the present invention, the method for manufacturing electrochemical device can form the doped-type metal oxide films via the arc plasma coating process, which can effectively increase the ion conduction speed and the response time of the doped-type metal oxide films, so can improve the characteristics of the electrochemical devices.

Moreover, according to one embodiment of the present invention, the method for manufacturing electrochemical device can form the doped-type metal oxide films via the arc plasma coating process, so the doped-type metal oxide films can have the Nano-porous structure, which can further improve the characteristics of the electrochemical devices.

Furthermore, according to one embodiment of the present invention, the method for manufacturing electrochemical device can be applied to various electrochemical devices, so is more comprehensive in use.

While the means of specific embodiments in present invention has been described by reference drawings, numerous modifications and variations could be made thereto by those skilled in the art without departing from the scope and spirit of the invention set forth in the claims. The modifications and variations should in a range limited by the specification of the present invention.

1. A method for manufacturing electrochemical device, comprising the following steps:
providing an electrically conductive substrate;
disposing a metal material or a metal oxide material on an anode of a plasma source of an arc plasma coating equipment;
coating an anode on the electrically conductive substrate by the arc plasma coating equipment via an arc plasma coating process, and doping the metal material or the metal oxide material into the anode via a phenomenon of electrons heating the anode of the plasma source;
coating an ion conductor layer on the anode by the arc plasma coating equipment via the arc plasma coating process;
coating a cathode on the ion conductor layer by the arc plasma coating equipment via the arc plasma coating process; and
coating a conductive film on the cathode by the arc plasma coating equipment via the arc plasma coating process to form an electrochemical device.

2. The method for manufacturing electrochemical device of claim 1, further comprising the following step:
doping the metal material or the metal oxide material into the ion conductor layer via the phenomenon of the electrons heating the anode of the plasma source.

3. The method for manufacturing electrochemical device of claim 2, further comprising the following step:
doping the metal material or the metal oxide material into the cathode via the phenomenon of the electrons heating the anode of the plasma source.

4. The method for manufacturing electrochemical device of claim 3, further comprising the following step:
doping the metal material or the metal oxide material into the conductive film via the phenomenon of the electrons heating the anode of the plasma source.

5. The method for manufacturing electrochemical device of claim 4, wherein the anode, the ion conductor layer, the cathode and the conductive film are doped-type metal oxide films after being formed by doping the metal material or the metal oxide material thereon.

6. The method for manufacturing electrochemical device of claim 4, wherein the metal material or the metal oxide material is doped into the anode, the ion conductor layer, the cathode and the conductive film after the metal material or the metal oxide material is mixed with plasma via heat vaporization.

7. The method for manufacturing electrochemical device of claim 1, wherein the electrochemical device is a secondary battery or an electrochromic device the metal material is Li, Mg or Na, and the metal oxide material is an oxide of Li, Mg or Na.

8. A method for manufacturing electrochemical device, comprising the following steps:
providing an electrically conductive substrate;
disposing a metal material or a metal oxide material on an anode of a plasma source of an arc plasma coating equipment; coating a cathode on the conductive substrate by the arc plasma coating equipment via an arc plasma coating process, and doping the metal material or the metal oxide material into the cathode via a phenomenon of electrons heating the anode of the plasma source;
coating an ion conductor layer on the cathode by the arc plasma coating equipment via the arc plasma coating process;
coating an anode on the ion conductor layer by the arc plasma coating equipment via the arc plasma coating process; and
coating a conductive film on the anode by the arc plasma coating equipment via the arc plasma coating process to form an electrochemical device.

9. The method for manufacturing electrochemical device of claim 8, further comprising the following step:
doping the metal material or the metal oxide material into the ion conductor layer via the phenomenon of the electrons heating the anode of the plasma source.

10. The method for manufacturing electrochemical device of claim 9, further comprising the following step:
doping the metal material or the metal oxide material into the anode via the phenomenon of the electrons heating the anode of the plasma source.

11. The method for manufacturing electrochemical device of claim 10, further comprising the following step:
doping the metal material or the metal oxide material into the conductive film via the phenomenon of the electrons heating the anode of the plasma source.

12. The method for manufacturing electrochemical device of claim 11, wherein the anode, the ion conductor layer, the cathode and the conductive film are doped-type metal oxide films after being formed by doping the metal material or the metal oxide material thereon.

13. The method for manufacturing electrochemical device of claim 11, wherein the metal material or the metal oxide material is doped into the anode, the ion conductor layer, the cathode and the conductive film after the metal material or the metal oxide material is mixed with plasma via heat vaporization.

14. The method for manufacturing electrochemical device of claim 8, wherein the electrochemical device is a secondary battery or an electrochromic device the metal material is Li, Mg or Na, and the metal oxide material is an oxide of Li, Mg or Na.

15-20. (canceled)
